(19) United States
(12) Patent Application Publication
(10) Pub. No.: US 2017/0006735 A1
(43) Pub. Date: Jan. 5, 2017

(54) COOLING DEVICE AND COOLING DEVICE MANUFACTURING METHOD

(71) Applicant: SANOH INDUSTRIAL CO., LTD, Tokyo (JP)

(72) Inventors: Yoshitaka Shibasaki, Koga-shi, Ibaraki (JP); Takuma Endo, Koga-shi, Ibaraki (JP); Takeo Oguri, Koga-shi, Ibaraki (JP); Katsutoshi Ishibashi, Koga-shi, Ibaraki (JP)

(73) Assignee: SANOH INDUSTRIAL CO., LTD., Tokyo (JP)

(21) Appl. No.: 15/115,098

(22) PCT Filed: Oct. 28, 2014
(86) PCT No.: PCT/JP2014/078655

§ 371 Date: Jul. 28, 2016

(30) Foreign Application Priority Data
Jan. 31, 2014 (JP) 2014-016989

(51) Int. Cl. H05K 7/20; F28F 9/007; F28F 3/02; F28F 9/00

(52) U.S. Cl. CPC H05K 7/20409; H05K 7/20218; F28F 9/001; F28F 9/0075; F28F 3/02; F28F 2265/32; F28F 2275/04

(57) ABSTRACT

A cooling device includes: a case that includes a supply port for supplying coolant to an interior of the case and a discharge port for discharging coolant at the interior of the case to an exterior of the case; plural fins that each have a plate shape, that are provided an exterior of at separations along their plate thickness direction, and that have coolant flowing between adjacent fins; projecting portions that are respectively formed at the fins, that project out along the plate thickness direction of the fins, and that abut adjacent fins; and restraining members that are respectively inserted through insertion holes respectively formed in the fins, that pierce through the plural fins, and that restrain relative movement between adjacent fins.

### TECHNICAL FIELD

The present invention relates to a cooling device and a cooling device manufacturing method.

### BACKGROUND ART

Japanese Patent Application Laid-Open (JP-A) No. 2007-335588 describes a liquid cooling type of cooling device (heat sink) in which plate shaped fins are arrayed an interior of a case, and the fins are joined to an inner face of the case.

### SUMMARY OF INVENTION

### Technical Problem

However, in cases in which positional misalignment of the fins has occurred during manufacturing, sometimes a desired cooling performance cannot be obtained, namely, there is a drop in cooling performance.

In consideration of the above circumstances, an issue of the present invention is to provide a cooling device and a cooling device manufacturing method that improve cooling performance, while suppressing positional misalignment of fins.

### Solution to Problem

A cooling device of a first aspect of the present invention includes: a case that includes a supply port for supplying coolant to an interior of the case and a discharge port for discharging coolant at the interior of the case to an exterior of the case; plural fins that each have a plate shape, that are provided at the interior of the case at separations along a plate thickness direction, and that have coolant flowing between adjacent fins; a projecting portion that is formed at each of the fins, that projects out along the plate thickness direction of the fins, and that abuts an adjacent fin; and a restraining member that is inserted through an insertion hole formed in each of the fins, that pierces through the plural fins, and that restrains relative movement between adjacent fins.

In the cooling device of the first aspect, heat from a cooling target is transferred to the case and the fins by disposing the cooling target so as to contact the case. The case and the fins are cooled by coolant supplied into the case. The heat of the cooling target is thereby captured by the coolant, and the cooling target is cooled.

Note that in the above cooling device, during manufacturing, by installing the fins at the interior of the case in a state in which the restraining member has been inserted through each insertion hole of the plural fins such that relative movement between adjacent fins has been restrained, relative positional misalignment between adjacent fins can be suppressed. This enables the flow of coolant at the interior of the case to be brought closer to the desired flow, thereby enabling a reduction in cooling performance to be suppressed. Moreover, the fins are installed at the interior of the case in a state in which the projecting portions formed on the fins have been made to abut adjacent fins. This enables a distance (separation) to be secured between adjacent fins. Namely, the flow rate of coolant flowing between adjacent fins can be adjusted by the height of the projecting portion, thereby enabling cooling performance to be improved.

Thus, the cooling device of the first aspect enables cooling performance to be improved, while suppressing positional misalignment of the fins.

A cooling device of a second aspect of the present invention is the cooling device of the first aspect in which the projecting portion is tube shaped and an interior of the projecting portion configures the insertion hole.

In the cooling device of the second aspect, the projecting portion is tube shaped and the interior thereof configures the insertion hole, thereby enabling the number of processes for work-processing the fins to be reduced compared, for example, to configurations in which a projecting portion is formed separately from an insertion hole.

A cooling device of a third aspect of the present invention is the cooling device of the second aspect in which the projecting portion is a tube shaped protruding portion formed by burring the fin.

In the cooling device of the third aspect, the projecting portion is a tube shaped protruding portion formed by burring the fin. This enables the projecting portion to be formed at the fin simply and at low cost compared, for example, to configurations in which a fin is formed by being machined and a projecting portion is provided to this fin, or in which an additional component is joined to a fin to form a projecting portion.

A cooling device of a fourth aspect of the present invention is the cooling device of any one of the first aspect to the third aspect in which the projecting portion is respectively formed at both end portion sides along a length direction of the fin.

In the cooling device of the fourth aspect, the projecting portions are respectively formed at both end portion sides along the length direction of the fins, thereby enabling relative positional misalignment of adjacent fins to be effectively suppressed. This also enables a distance (separation) between adjacent fins to be reliably secured.

A cooling device of a fifth aspect of the present invention is the cooling device of any one of the first aspect to the fourth aspect in which an end face of each fin is brazed to an inner face of the case.

In the cooling device of the fifth aspect, the end face of each fin is brazed to the inner face of the case, thereby improving the rigidity of the case. This also improves the heat transfer efficiency between the fins and the case.

A cooling device manufacturing method of a sixth aspect of the present invention includes: an assembly process of arraying plural plate shaped fins each formed with a projecting portion projecting out along a plate thickness direction of the fin and an insertion hole, while inserting a restraining member through the insertion holes of the fins, such that the projecting portion of each fin abuts an adjacent fin; and an installation process of installing the fins at an interior of a case including a supply port for supplying coolant to the interior of the case, and a discharge port for discharging coolant at the interior of the case to an exterior of the case.

In the cooling device manufacturing method of the sixth aspect, in the assembly process, the plural fins are arrayed such that the projecting portions of the fins abut adjacent fins while inserting the restraining member through the respective insertion holes of the plural fins, such that the positioning of the fins is easily performed. In the installation process, the fins are installed at the interior of the case in a state in which relative movement between adjacent fins has been restrained by the restraining member, thereby enabling relative positional misalignment between adjacent fins to be suppressed. A cooling device manufactured in this manner enables the flow of coolant at the interior of the case to be brought closer to the desired flow, thereby enabling a reduction in cooling performance to be suppressed.

In the above cooling device manufacturing method, in the assembly process, the plural fins are arrayed such that the projecting portions formed at the fins abut adjacent fins, thereby enabling a distance (separation) to be secured between adjacent fins. This separation is also secured when installing the fins at the interior of the case in the installation process. In a cooling device manufactured in this manner, the flow rate of coolant flowing between adjacent fins can be adjusted by the height of the projecting portions, thereby enabling cooling performance to be improved.

Thus, the manufacturing method cooling device of the sixth aspect enables manufacture of a cooling device that improves cooling performance while suppressing positional misalignment of the fins.

A cooling device manufacturing method of a seventh aspect of the present invention is the cooling device manufacturing method of the sixth aspect, further including a working process of forming a tube shaped protruding portion serving as the projecting portion configured with an interior thereof configuring the insertion hole, by burring a plate shaped fin prior to the assembly process.

In the cooling device manufacturing method of the seventh aspect, in the working process, the tube shaped protruding portion serving as the projecting portion configured with the interior thereof configuring the insertion hole is formed by burring a fin. This enables the projecting portion to be formed at the fin simply and at low cost compared, for example, to configurations in which a fin is formed by being machined and a projecting portion is provided to this fin, or configurations in which an additional component is joined to a fin to form a projecting portion.

A cooling device manufacturing method of an eighth aspect of the present invention is the cooling device manufacturing method of the seventh aspect in which, in the working process, the projecting portion is respectively formed at both end portion sides along a length direction of the fin.

In the cooling device manufacturing method of the eighth aspect, relative positional alignment between adjacent fins can be effectively suppressed by respectively forming the projecting portion at both end portion sides along the length direction of the fin in the working process. This also enables the distance (separation) between adjacent fins to be reliably secured.

A cooling device manufacturing method of a ninth aspect of the present invention is the cooling device manufacturing method of any one of the sixth aspect to the eight aspect in which, in the installation process, an end face of each fin is brazed to an inner face of the case.

In the cooling device manufacturing method of the ninth aspect, the end face of each fin is brazed to the inner face of the case in the installation process, thereby improving the rigidity of the case of the cooling device that has been manufactured in this manner, and also improving the heat transfer efficiency between the fins and the case.

### Advantageous Effects of Invention

As explained above, the present invention enables the provision of a cooling device and a cooling device manufacturing method that improve cooling performance while suppressing positional misalignment of fins.

### BRIEF DESCRIPTION OF DRAWINGS

FIG. 1 is a perspective view of a cooling device of a first exemplary embodiment.

FIG. 2 is an exploded perspective view of a cooling device of the first exemplary embodiment.

FIG. 3 is a plan view of a lid body of a case a cooling device of the first exemplary embodiment in an opened state.

FIG. 4 is a cross-section along line 4-4 in FIG. 1.

FIG. 5 is an enlarged partial cross-section of a portion indicated by the arrow 5 in FIG. 3.

FIG. 6 is a perspective view of fins and restraining members, illustrating an operation to insert the restraining members through insertion holes of the fins employed in the cooling device of the first exemplary embodiment.

FIG. 7 is a plan view illustrating a flow of coolant at the interior of a case of a cooling device of the first exemplary embodiment, in a state in which a lid body of the case has been opened.

FIG. 8 is a cross-section along line 8-8 in FIG. 7.

FIG. 9 is a plan view of a state in which restraining members have been passed through fins employed in a cooling device of a second exemplary embodiment.

FIG. 10 is an enlarged partial cross-section of a portion indicated by the arrow 10 in FIG. 9.

FIG. 11 is a partial plan view illustrating a flow of coolant at the interior of a case of a cooling device of the second exemplary embodiment, in a state in which a lid body of the case has been opened.

FIG. 12 is a plan view of a state in which restraining members have been passed through fins employed in a cooling device of a third exemplary embodiment.

FIG. 13 is an enlarged partial cross-section of a portion indicated by the arrow 13 in FIG. 12.

FIG. 14 is a face-on view of a fin employed in a cooling device of the third exemplary embodiment.

FIG. 15 is a cross-section corresponding to FIG. 8, illustrating a flow of coolant at the interior of a case of a cooling device of the third exemplary embodiment.

FIG. 16 is a plan view illustrating a flow of coolant at the interior of a case of a cooling device of a fourth exemplary embodiment, in a state in which a lid body of the case has been opened.

### DESCRIPTION OF EMBODIMENTS

Explanation follows regarding a cooling device and a cooling device manufacturing method of exemplary embodiments according to the present invention, with reference to the drawings. Note that the arrow X, arrow Y, and arrow Z illustrated in each of the drawings as appropriate respectively indicate the device width direction, the device depth direction, and the device thickness direction of the cooling device, and explanation follows with the arrow Z direction as the up-down direction.

### First Exemplary Embodiment

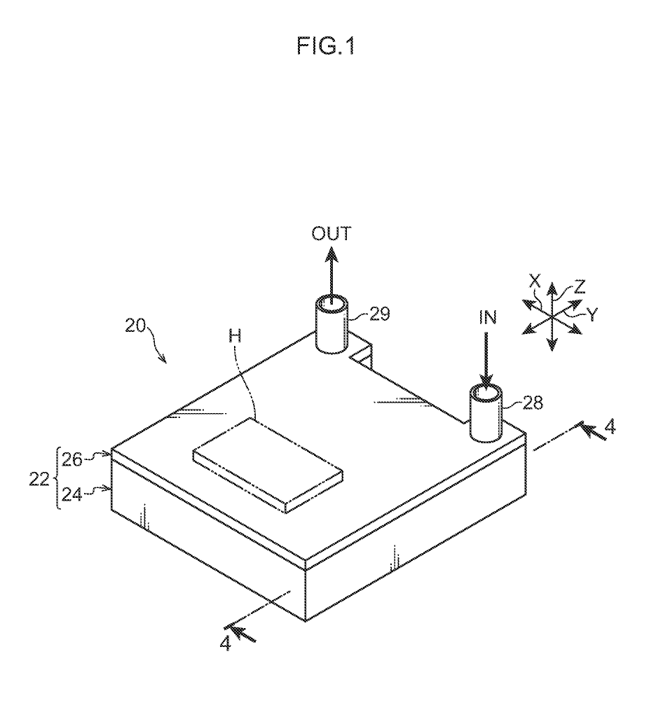

FIG. 1 illustrates a cooling device 20 of a first exemplary embodiment (hereafter referred to as present exemplary embodiment). The cooling device 20 is employed to cool a heat generating body (a cooling target) such as a CPU or power semiconductor elements. Specifically, the cooling device 20 is placed in contact with a heat generating body H, and the heat generating body H is cooled by transferring the heat of the heat generating body H to a coolant flowing at an interior of the cooling device 20.

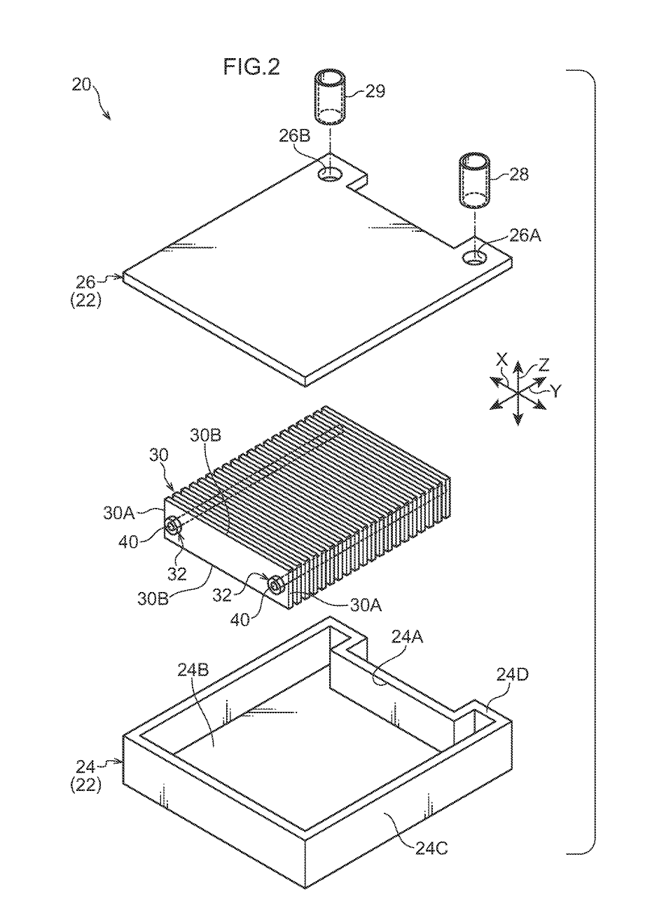

As illustrated in FIG. 1 and FIG. 2, the cooling device 20 of the present exemplary embodiment includes a case 22, fins 30 installed at the interior of the case 22, and restraining members 40 piercing through the fins 30.

As illustrated in FIG. 2, the case 22 includes a case main body 24, and a lid body 26 that closes off an opening 24A in the device thickness direction of the case main body 24.

The case main body 24 is configured by a plate shaped bottom portion 24B, and a side wall portion 24C that projects upward at an outer peripheral edge of the bottom portion 24B. The case main body 24 is formed using a metal material (such as aluminum or copper).

As illustrated in FIG. 1 and FIG. 2, the lid body 26 has a plate shape, and is joined to an end face 24D at the opposite side of the side wall portion 24C of the case main body 24 to the bottom portion 24B side. Note that in the present exemplary embodiment, the lid body 26 is joined to the end face 24D of the case main body 24 by brazing. The lid body 26 is also formed using a metal material (such as aluminum or copper).

A supply port 26A for supplying coolant (such as cooling water or oil) into the case 22 is formed at one end side in the device width direction of the lid body 26. A supply pipe 28 (see FIG. 1) that is coupled to a coolant supply source is connected to the supply port 26A.

A discharge port 26B for discharging coolant from at the interior of the case 22 is formed at another end side in the device width direction of the lid body 26. A discharge pipe 29 (see FIG. 1) is connected to the discharge port 26B.

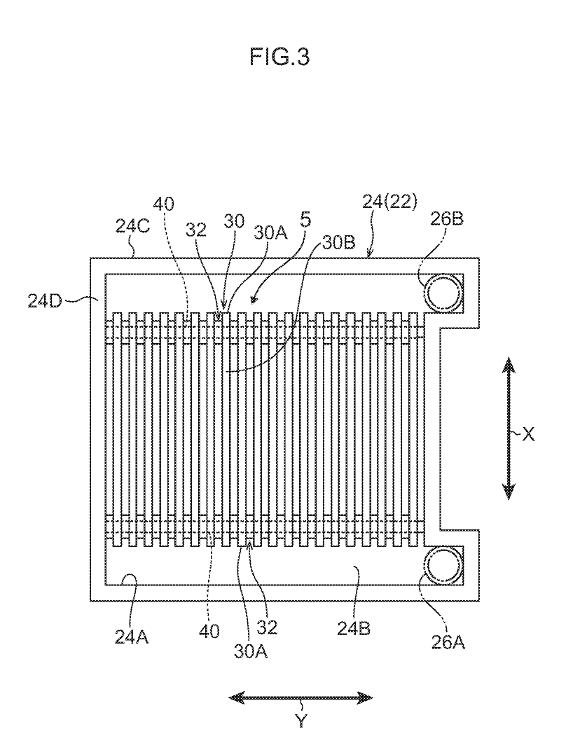

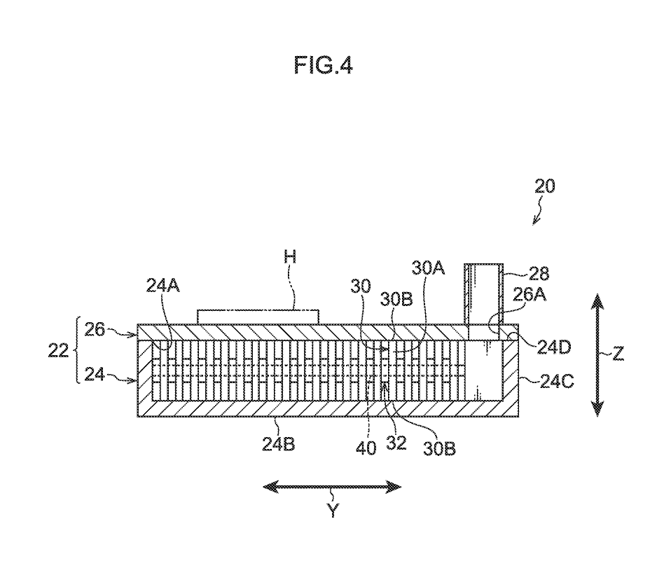

As illustrated in FIG. 3 and FIG. 4, the fins 30 are each configured in an elongated, flat plate shape, and plural of the fins 30 are provided at the interior of the case 22 at separations along a fin plate thickness direction (the same direction as the device depth direction in the present exemplary embodiment). The fins 30 are formed using a metal material (such as aluminum or copper). The fin length direction of the fins 30 in the present exemplary embodiment is the same direction as the device width direction.

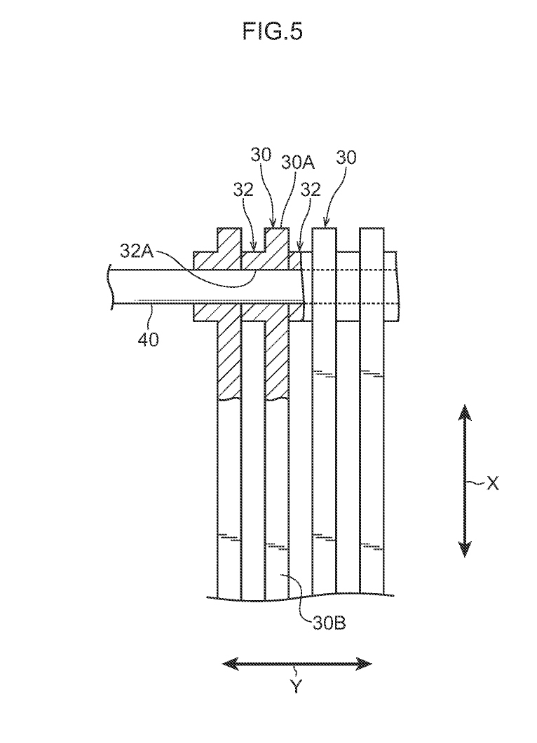

Projecting portions 32 that project out along the fin plate thickness direction are formed on each fin 30. Each projecting portion 32 has a tube shape with a leading end portion that abuts an adjacent fin 30. To explain specifically, as illustrated in FIG. 5, each projecting portion 32 is a circular tube shaped protruding portion that is formed on the fin 30 by burring. An interior of the projecting portion 32 configures an insertion hole 32A through which the respective restraining member 40 is inserted. Note that, by inserting the restraining members 40 through the respective insertion holes 32A, the restraining members 40 pierce through the fin plate thickness direction of the fins 30. Note that some of the fins 30 are omitted from illustration in FIG. 5.

As illustrated in FIG. 4, both end faces 30B in the fin width direction (the same direction as the device thickness direction in the present exemplary embodiment) of each fin 30 are respectively joined to an inner face (bottom face) of the bottom portion 24B of the case 22 and to an inner face (ceiling face) of the lid body 26, and the fins 30 are installed at the interior of the case.

Note that in the present exemplary embodiment, both end faces 30B in the fin width direction of each fin 30 are respectively joined to the inner face of the bottom portion 24B of the case 22 and to the inner face of the lid body 26 by brazing.

As illustrated in FIG. 4 and FIG. 5, each restraining member 40 is a circular column shaped rod member that is inserted through the respective insertion holes 32A of the plural fins 30 so as to pierce through the plural fins 30. The axial direction of the restraining members 40 of the present exemplary embodiment is the same direction as the device depth direction, and both end portions in the axial direction of each restraining member 40 are respectively fixed to opposing inner faces of the case 22.

In the present exemplary embodiment, the projecting portions 32 are respectively formed at both end portion 30A sides in the fin length direction of each fin 30. The two restraining members 40 are thereby respectively inserted through both insertion holes 32A of each fin 30.

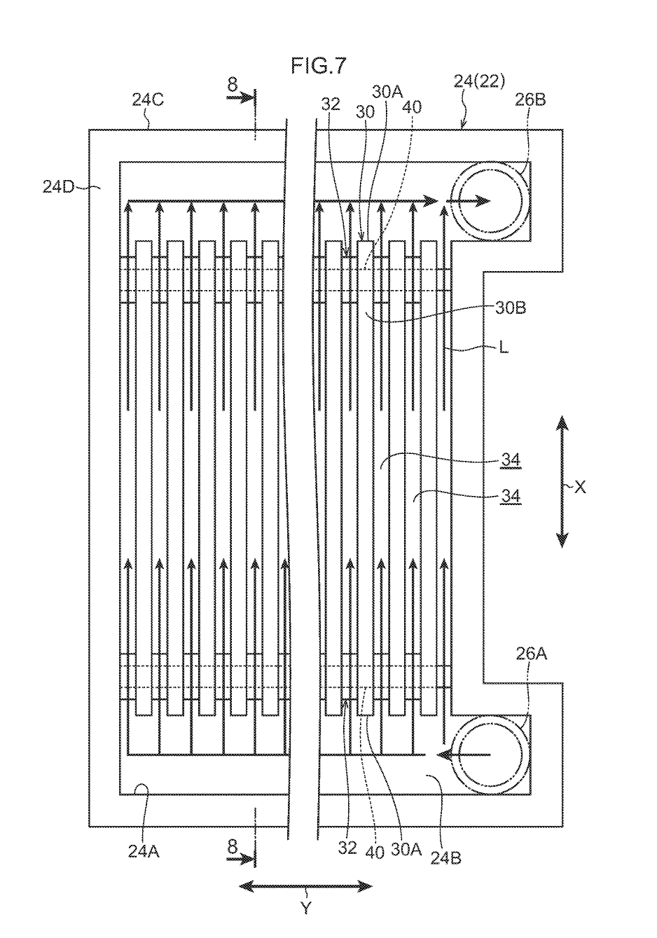

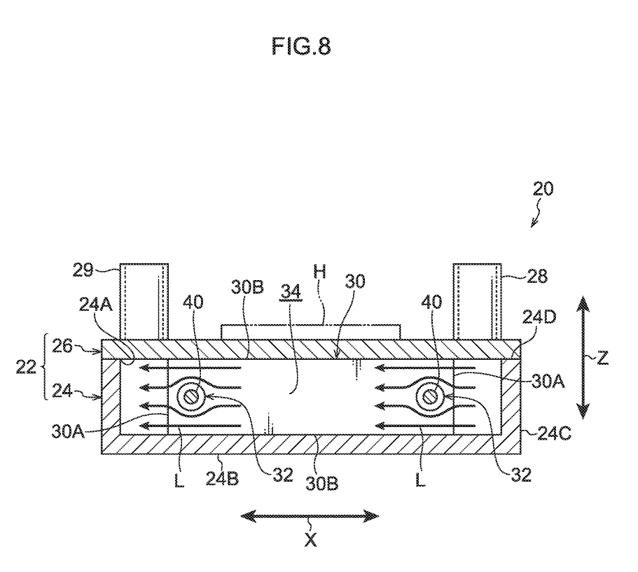

As illustrated in FIG. 7 and FIG. 8, a separation between adjacent fins 30 (the height of the projecting portions 32) is set at a size enabling coolant to flow from the supply port 26A toward the discharge port 26B.

Explanation follows regarding a manufacturing method of the cooling device 20 of the present exemplary embodiment.

### Working Process

First, burring is performed on the fins 30 made of metal material formed in a plate shape. Thus, the tube shaped projecting portions 32 with an interior thereof configuring the insertion holes 32A are formed on each fin 30. Each projecting portion 32 is a circular tube shaped protruding portion formed by burring. The projecting portions 32 are respectively formed at both end portion 30A sides in the fin length direction of each fin 30.

### Assembly Process

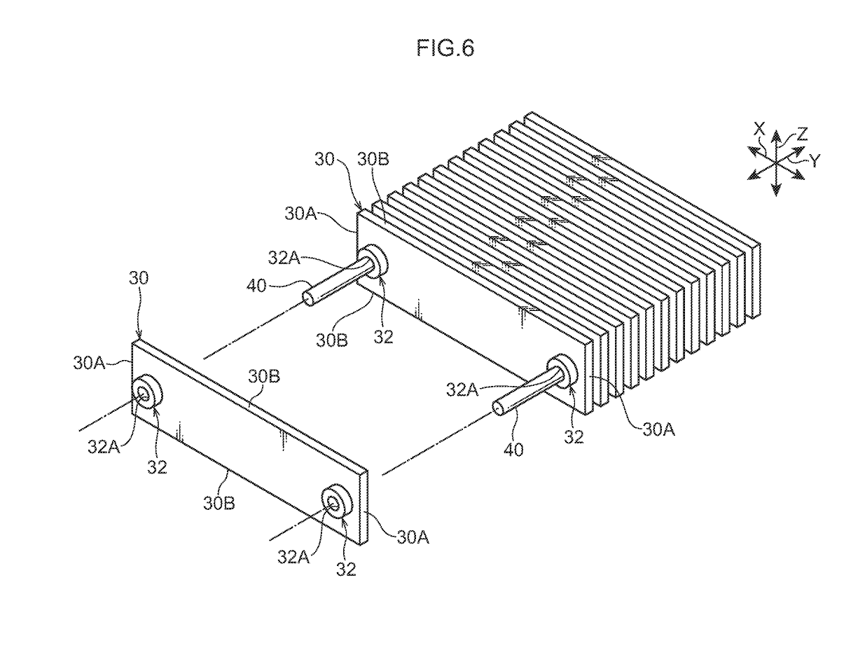

Next, as illustrated in FIG. 6, the two restraining members 40 are disposed parallel to each other with a separation therebetween. Each restraining member 40 is inserted through the insertion hole 32A corresponding to the respective fin 30. After each fin 30 has been inserted as far as a specific position of each restraining member 40, each restraining member 40 is inserted through the corresponding insertion hole 32A of the next fin 30, and the plural fins 30 are arrayed in the fin plate thickness direction. When this is performed, the plural fins 30 are arrayed such that the projecting portions 32 of each fin 30 abut an adjacent fin 30.

Note that in the assembly process, the plural fins 30 are arrayed such that the projecting portions 32 of each fin 30 abut an adjacent fin 30 while the restraining members 40 are inserted through the respective insertion holes 32A of the plural fins 30, thereby enabling the positioning of the fins 30 to be easily performed.

### Installation Process

Next, the plural fins 30 with the restraining members 40 piercing through are installed on the bottom portion 24B of the case main body 24 (the state illustrated in FIG. 3). The opening 24A of the case main body 24 is then closed off by the lid body 26. Both end faces 30B of each fin 30 respectively contact the inner face of the bottom portion 24B of the case 22 and the inner face of the lid body 26 when this is performed.

Both end faces 30B of each fin 30 are then respectively joined to the inner face of the bottom portion 24B of the case 22 and the inner face of the lid body 26 by brazing. Manufacturing of the cooling device 20 is completed in this manner.

Note that in the assembly process, the plural fins 30 are arrayed such that the projecting portions 32 formed at each fin 30 abut an adjacent fin 30 thereby enabling a distance (separation) between adjacent fins 30 to be secured. This separation is also secured when the fins 30 are installed at the interior of the case 22 in the installation process.

Explanation follows regarding operation and advantageous effects of the cooling device 20 of the present exemplary embodiment.

As illustrated in FIG. 1, in the cooling device 20, by disposing the heat generating body H so as to contact the case 22, heat from the heat generating body H is transferred to the case 22 and also to the fins 30 through the case 22. The case 22 and the fins 30 are cooled by heat exchange with the coolant supplied into the case 22. The heat of the heat generating body H is captured by the coolant, and the heat generating body H is cooled in this manner.

Note that in the cooling device 20, during manufacturing (the assembly process), the fins 30 are installed at the interior of the case 22 in a state in which the restraining members 40 have been inserted through the respective projecting portions 32 of the plural fins 30, and relative movement (relative movement in a direction orthogonal to the fin plate thickness direction in the present exemplary embodiment) of adjacent fins 30 has been restrained. This enables relative positional misalignment (positional misalignment in a direction orthogonal to the fin plate thickness direction in the present exemplary embodiment) of adjacent fins 30 to be suppressed. This enables the flow of coolant at the interior of the case 22 to be brought closer to the desired flow, thereby enabling a reduction in cooling performance to be suppressed. Moreover, the fins 30 are installed at the interior of the case 22 in a state in which the projecting portions 32 formed on each fin 30 have been made to abut an adjacent fin 30. This enables a distance (separation) to be secured between adjacent fins 30. Namely, the flow rate of coolant flowing between adjacent fins 30 can be adjusted according to the height of the projecting portions 32, thereby enabling cooling performance to be improved.

The interior of each projecting portion 32 is configured in a tube shape configuring the insertion hole 32A, thereby enabling the number of processes for work-processing the fins 30 to be reduced. In particular, each projecting portion 32 is configured by a tube shaped protruding portion formed in the fin 30 by burring, thereby enabling the projecting portions 32 to be formed on the fins 30 simply and at low cost.

The projecting portions 32 are respectively formed at both end portion 30A sides in the fin length direction of each fin 30, thereby enabling relative positional misalignment between adjacent fins 30 to be effectively suppressed. This also enables the distance (separation) between adjacent fins 30 to be reliably secured. This further improves the cooling performance of the cooling device 20.

Both end faces 30B of each fin 30 are respectively joined by brazing to the inner face of the bottom portion 24B of the case 22 and the inner face of the lid body 26, thereby improving the rigidity of the case 22. This also improves the heat transfer efficiency between the fins 30 and the case 22, further improving the cooling performance of the cooling device 20.

As illustrated in FIG. 7 and FIG. 8, in the cooling device 20 of the present exemplary embodiment, the entrance to gaps (flow paths 34) formed between adjacent fins 30 is made narrower by the projecting portions 32 at the supply port 26A side. Thus, coolant that has been supplied through the supply port 26A flows into the flow paths 34 that are at positions far away from the supply port 26A along the device depth direction. Thus, the fins 30 configuring the flow paths 34 that are at positions far away from the supply port 26A are also cooled by the coolant. This enables the heat generating body H that has been placed in contact with the cooling device 20 to be cooled substantially uniformly. Namely, in the cooling device 20 of the present exemplary embodiment, an advantageous effect of regulating the coolant can be obtained by the configuration of the fins 30. Note that the flow of coolant is illustrated by the arrows L in FIG. 7 and FIG. 8.

As described above, the cooling device 20 of the present exemplary embodiment enables cooling performance to be improved, while suppressing positional misalignment of the fins 30.

In the present exemplary embodiment, the projecting portions 32 are formed on each fin 30 by burring; however, the present invention is not limited to this configuration. For example, the projecting portions 32 may be formed while a fin is being formed by machining. Alternatively, a through-hole may be formed in each fin 30, and each projecting portion 32 formed by joining a tube shaped component to an edge of the through-hole. Note that the above-described configurations may also be applied to second to fourth exemplary embodiments, described later.

The present exemplary embodiment is configured such that the projecting portions 32 are respectively formed at both end portion 30A sides in the fin length direction of each fin 30; however, the present invention is not limited to this configuration. For example, the projecting portions 32 may be formed on a portion (such as a center portion) other than the both end portion 30A sides in the fin length direction of each fin 30, or a projecting portion 32 may be formed at only one end portion 30A side in the fin length direction of each fin 30. Note that the above-described configurations may also be applied to the second to fourth exemplary embodiments, described later.

The present exemplary embodiment is configured such that the interior of the projecting portion 32 configures the insertion hole 32A; however, the present invention is not limited to this configuration. For example, a protruding portion and an insertion hole may be formed separately to each other on the fin 30. Note that the above-described configurations may also be applied to the second to fourth exemplary embodiments, described below.

### Second Exemplary Embodiment

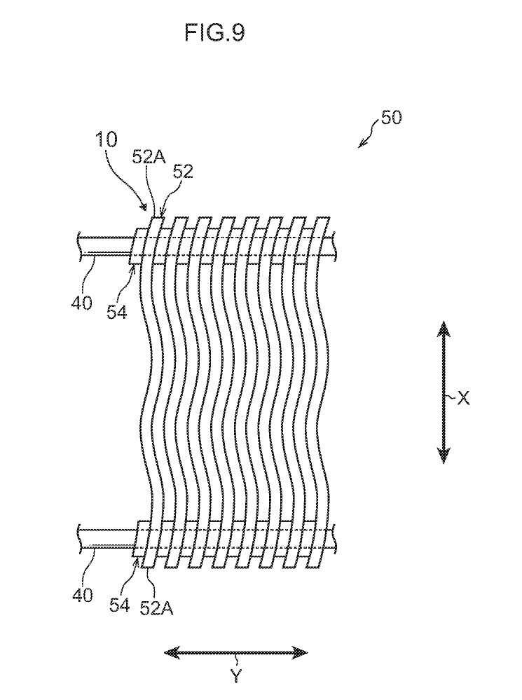

FIG. 9 to FIG. 11 illustrate a cooling device 50 of the second exemplary embodiment. The cooling device 50 of the present exemplary embodiment has a similar configuration to the cooling device 20 of the first exemplary embodiment excluding the configuration of fins 52, and so similar explanation is omitted. Note that similar configuration to the first exemplary embodiment is appended with the same reference numerals. Some of the fins 52 are omitted from illustration in FIG. 9 to FIG. 11.

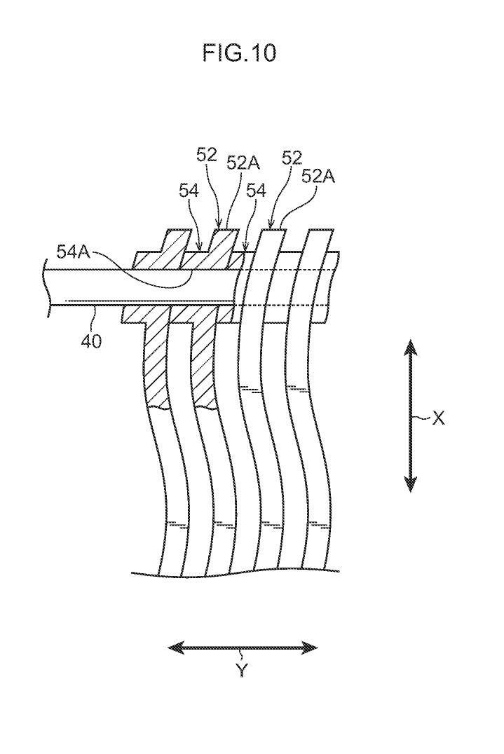

As illustrated in FIG. 9 and FIG. 10, each fin 52 is configured in an elongated wave plate shape. Note that the fin length direction of the fins 52 of the present exemplary embodiment is the same direction as the device width direction, and each fin 52 has a wave plate shape with amplitude that moves to the left and right (in the fin plate thickness direction) on progression along the fin length direction. Projecting portions 54 are respectively formed by burring at both end portion 52A sides in the fin length direction of each fin 52. The respective restraining member 40 is inserted through an insertion hole 54A configured at an interior of respective projecting portion 54.

Next, explanation follows regarding operation and advantageous effects of the cooling device 50 of the present exemplary embodiment. Note that explanation regarding operation and advantageous effects that are similar to the operation and advantageous effects obtained in the first exemplary embodiment is omitted.

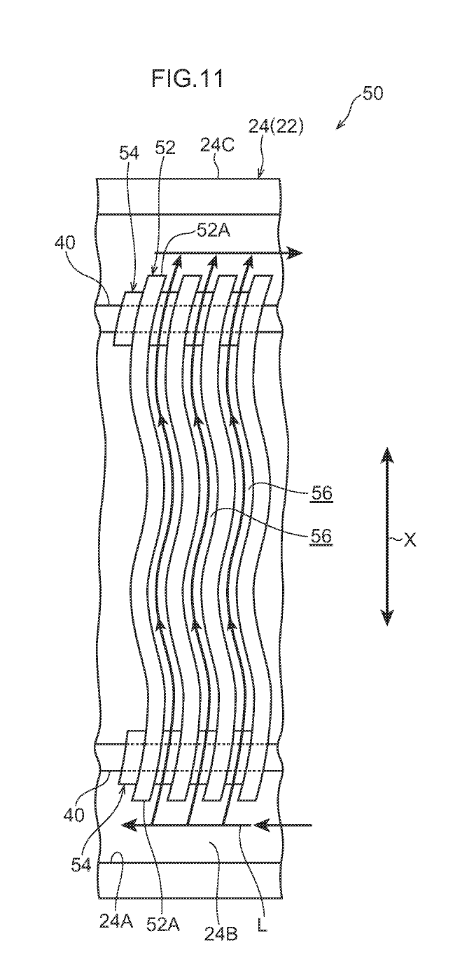

As illustrated in FIG. 11, the fins 52 are each configured in a wave plate shape, and therefore have a wider plate face surface area, namely, a wider heat dissipating surface area, than the fins 30 of the first exemplary embodiment. Thus, heat in the fins 52 is efficiently captured by coolant flowing along flow paths 56 formed between adjacent fins 52. The cooling performance of the cooling device 50 is thereby improved. Note that the flow of coolant is indicated by the arrows L in FIG. 11.

Note that the cooling device 50 of the present exemplary embodiment may be manufactured by the same manufacturing method as the manufacturing method of the cooling device 20 of the first exemplary embodiment.

In the cooling device 50 of the present exemplary embodiment, the fins 52 are each configured in an elongated wave plate shape; however, the present invention is not limited to this configuration. For example, the fins 52 may each be configured in a zigzag plate shape or a rectangular wave plate shape.

### Third Exemplary Embodiment

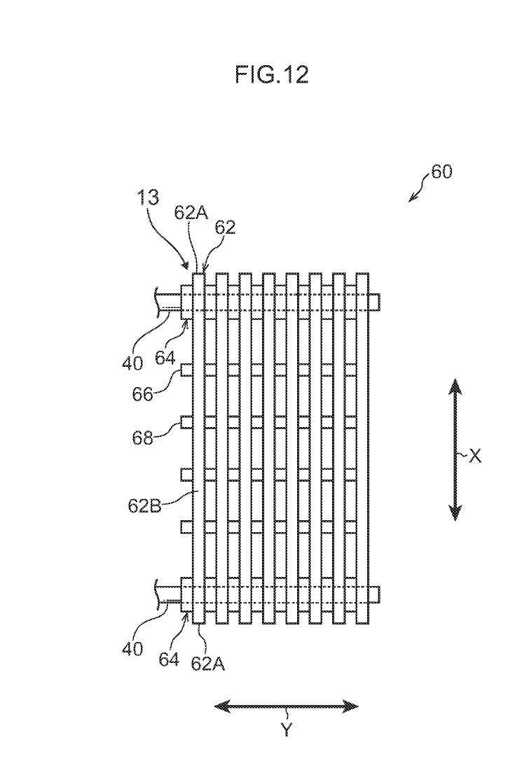

FIG. 12 to FIG. 15 illustrate a cooling device 60 of the third exemplary embodiment. Note that the cooling device 60 of the present exemplary embodiment has a similar configuration to the cooling device 20 of the first exemplary embodiment excluding the configuration of fins 62, and so similar explanation is omitted. Note that similar configuration to the first exemplary embodiment is appended with the same reference numerals. Some of the fins 62 are omitted from illustration in FIG. 12.

As illustrated in FIG. 12 to FIG. 14, each fin 62 is configured in an elongated flat plate shape. Note that the fin length direction of the fins 62 of the present exemplary embodiment is the same direction as the device width direction. Projecting portions 64 formed by burring are respectively formed at both end portion 62A sides in the fin length direction of each fin 62. The respective restraining member 40 is inserted through an insertion hole 64A configured at an interior of the respective projecting portion 64.

Ridge portions 66 and ridge portions 68 that each project out in the fin plate thickness direction at the same side as the projection side of the projecting portions 64 are respectively formed on each fin 62. Each ridge portion 66 extends in a straight line from one end face 62B toward another end face 62B side in the fin width direction of the fin 62, and terminates partway. Each ridge portion 68 extends in a straight line from the other end face 62B toward the one end face 62B side in the fin width direction of the fin 62, and terminates partway.

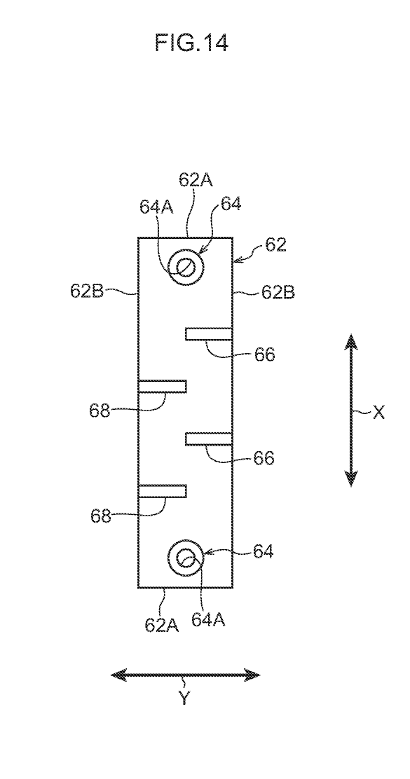

As illustrated in FIG. 14, the ridge portions 66 and the ridge portions 68 are formed alternately in the fin length direction with a separation therebetween.

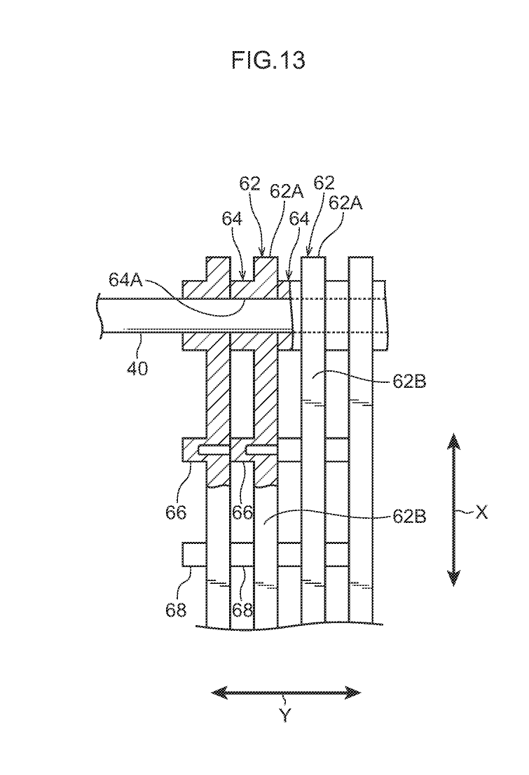

As illustrated in FIG. 12 and FIG. 13, in the present exemplary embodiment, the ridge portions 66 and the ridge portions 68 each abut an adjacent fin 62. Flow paths 69 (flow paths that snake along the device thickness direction) are thereby formed snaking between adjacent fins 62.

Next, explanation follows regarding operation and advantageous effects of the cooling device 60 of the present exemplary embodiment. Note that explanation regarding operation and advantageous effects that are similar to the operation and advantageous effects obtained in the first exemplary embodiment is omitted.

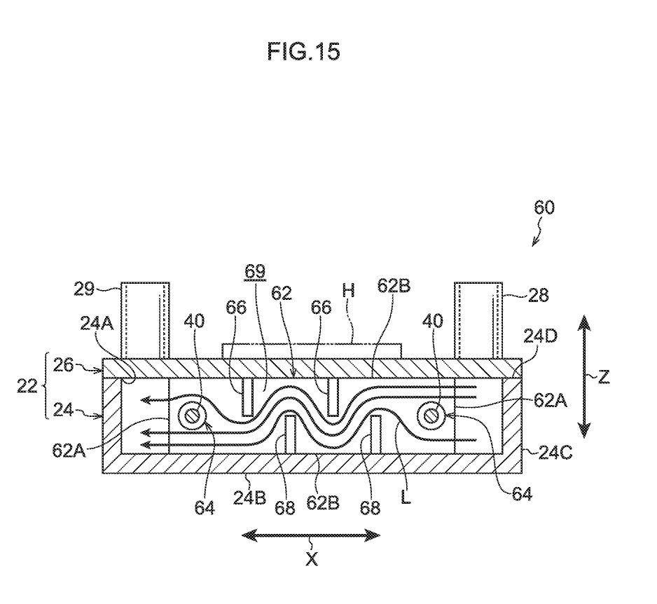

As illustrated in FIG. 15, the ridge portions 66 and the ridge portions 68 that abut an adjacent fin 62 are formed on each fin 62, thereby forming the flow paths 69 that snake between adjacent fins 62, such that a turbulent flow occurs in the coolant flowing along the flow paths 69. The advantageous effect in which coolant captures heat from the fins 62 (cooling the fins 62) is improved by the turbulent flow occurring in this manner. Thus, the cooling performance of the cooling device 60 is improved. Note that the flow of coolant is indicated by the arrows L in FIG. 15.

Note that the cooling device 60 of the third exemplary embodiment may be manufactured by the same manufacturing method as the manufacturing method of the cooling device 20 of the first exemplary embodiment.

In the cooling device 60 of the third exemplary embodiment, the fins 62 are each configured in a flat plate shape; however, the present invention is not limited to this configuration. For example, configuration may be in a wave plate shape, similarly to the fins 52 in the second exemplary embodiment.

The cooling device 60 of the third exemplary embodiment is configured such that the ridge portions 66 and the ridge portions 68 each extend in a straight line; however, the present invention is not limited to this configuration. For example, the ridge portions 66 and the ridge portions 68 may each be configured extending in a curved shape, a zigzag shape, or a stepped shape. The ridge portions 66 and the ridge portions 68 may alternatively each be formed in a column shape.

### Fourth Exemplary Embodiment

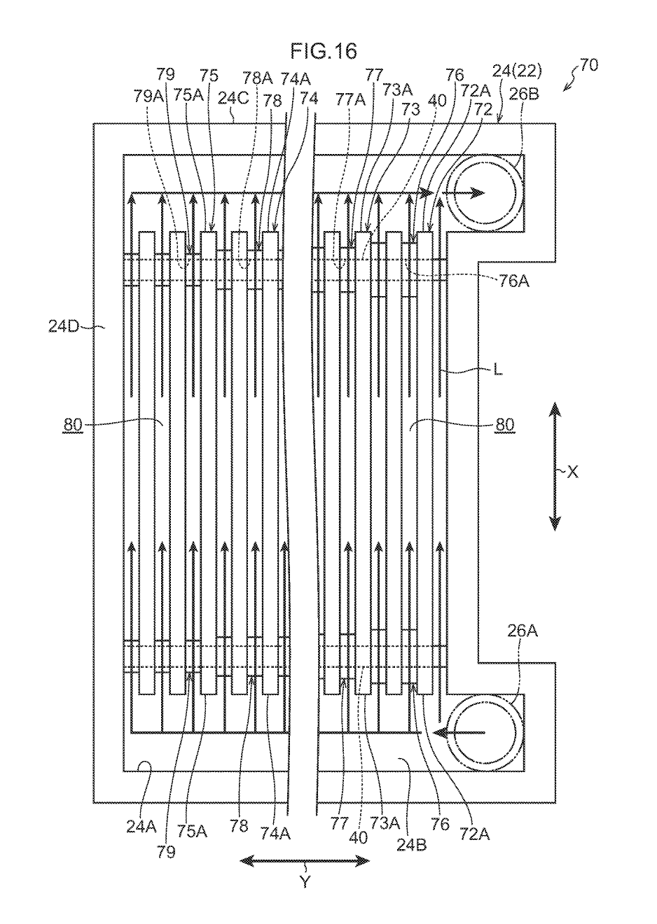

FIG. 16 illustrates a cooling device 70 of the fourth exemplary embodiment. Note that the cooling device 70 of the present exemplary embodiment has a similar configuration to the cooling device 20 of the first exemplary embodiment excluding the configuration of fins 72 to 75, and so similar explanation is omitted. Note that similar configuration to the first exemplary embodiment is appended with the same reference numerals.

As illustrated in FIG. 16, in the cooling device 70 of the present exemplary embodiment, plural each of plural types (four types in the present exemplary embodiment) of the fins 72 to 75 are employed. The fins 72 are disposed in a region that is nearest to the supply port 26A. The fins 75 are disposed in a region that is furthest from the supply port 26A. The fins 73 are disposed adjacent to the region in which the fins 72 are disposed, and the fins 74 are disposed adjacent to the region in which the fins 75 are disposed.

The fins 72 to 75 of the present exemplary embodiment are each configured in an elongated flat plate shape. Note that the fin length direction of each of the fins 72 to 75 of the present exemplary embodiment is the same direction as the device width direction. Projecting portions 76 to 79 are respectively formed by burring at both end portion 72A to 75A sides in the fin length direction of each of the fins 72 to 75. The respective restraining member 40 is inserted through an insertion hole 76A to 79A configured at an interior of the respective projecting portion 76 to 79. Note that in the present exemplary embodiment, the projection heights of each of the projecting portions 76 to 79 are set at the same height.

An outer diameter of the projecting portions 76 of each fin 72 is set larger than an outer diameter of the projecting portions 77 of each fin 73. The outer diameter of the projecting portions 77 of each fin 73 is set larger than an outer diameter of the projecting portions 78 of each fin 74. The outer diameter of the projecting portions 78 of each fin 74 is set larger than an outer diameter of the projecting portions 78 of each fin 74. Namely, fins disposed in regions nearer to the supply port 26A are set with projecting portions with a larger outer diameter.

Next, explanation follows regarding operation and advantageous effects of the cooling device 70 of the present exemplary embodiment. Note that explanation regarding operation and advantageous effects that are similar to the operation and advantageous effects obtained in the first exemplary embodiment is omitted.

As illustrated in FIG. 16, in the cooling device 70, the outer diameter of the projecting portions 76 of the fins 72 disposed in the region near to the supply port 26A is set larger than the outer diameter of the projecting portions 77 of the fins 73 disposed in a region that is further away from the supply port 26A than the fins 72. Thus, an entrance to a gap (flow path 80) formed between adjacent fins 73 is wider than an entrance to a gap (flow path 80) formed between adjacent fins 72. Thus, coolant that has been supplied through the supply port 26A also flows into the flow paths 80 at positions far away from the supply port 26A along the device depth direction. Namely, since the coolant travels as far as a back side (the opposite side to the supply port 26A) in the device depth direction of the case 22, an advantageous effect of regulating the coolant in the cooling device 70 is further obtained. Note that the flow of coolant is indicated by the arrows L in FIG. 16.

Note that the cooling device 70 of the fourth exemplary embodiment may be manufactured by the same manufacturing method as the manufacturing method of the cooling device 20 of the first exemplary embodiment.

The present invention has been explained above with reference to exemplary embodiments; however, these exemplary embodiments are merely examples, and various modifications may be implemented within a range not departing from the spirit of the present invention. Obviously, the scope of rights of the present invention is not limited by these exemplary embodiments.

The entire content of the disclosure of Japanese Patent Application No. 2014-016989 filed Jan. 31, 2014 is incorporated by reference in the present specification.

All publications, patent applications and technical standards mentioned in the present specification are incorporated by reference in the present specification to the same extent as if the individual publication, patent application, or technical standard was specifically and individually indicated to be incorporated by reference.

1. A cooling device comprising:
a case that includes a supply port for supplying coolant to an interior of the case and a discharge port for discharging coolant at the interior of the case to an exterior of the case;
a plurality of fins that each have a plate shape, that are provided at the interior of the case at separations along a plate thickness direction, and that have coolant flowing between adjacent fins;
a projecting portion that is formed at each of the fins, that projects out along the plate thickness direction of the fins, and that abuts an adjacent fin; and
a restraining member that is inserted through an insertion hole formed in each of the fins, that pierces through the plurality of fins, and that restrains relative movement between adjacent fins.

2. The cooling device of claim 1, wherein the projecting portion is tube shaped and an interior of the projecting portion configures the insertion hole.

3. The cooling device of claim 2, wherein the projecting portion is a tube shaped protruding portion formed by burring the fin.

4. The cooling device of claim 1, wherein the projecting portion is respectively formed at both end portion sides along a length direction of the fin.

5. The cooling device of claim 1, wherein an end face of each fin is brazed to an inner face of the case.

6. A cooling device manufacturing method, comprising:
arraying a plurality of plate shaped fins each formed with a projecting portion projecting out along a plate thickness direction of the fin and an insertion hole, while inserting a restraining member through the insertion holes of the fins, such that the projecting portion of each fin abuts an adjacent fin; and
installing the fins at an interior of a case including a supply port for supplying coolant to the interior of the case, and a discharge port for discharging coolant at the interior of the case to an exterior of the case.

7. The cooling device manufacturing method of claim 6, further comprising:
forming a tube shaped protruding portion serving as the projecting portion with an interior thereof configuring the insertion hole, by burring a plate shaped fin.

8. The cooling device manufacturing method of claim 7, comprising forming the projecting portion at both respective end portion sides along a length direction of the fin.

9. The cooling device manufacturing method of claim 6, comprising brazing an end face of each fin to an inner face of the case.
